(19) United States
(12) Patent Application Publication
(10) Pub. No.: US 2005/0147766 A1
(43) Pub. Date: Jul. 7, 2005

(54) Process for manufacturing pattern forming body

(76) Inventor: Daigo Aoki, Tokyo (JP)

Correspondence Address: SEYFARTH SHAW, 55 EAST MONROE STREET, SUITE 4200, CHICAGO, IL, 60603-5803, US

(21) Appl. No.: 11/058,584

(22) Filed: Feb. 15, 2005

Related U.S. Application Data
(62) Division of application No. 10/316,652, filed on Dec. 11, 2002, now abandoned.

(30) Foreign Application Priority Data
Dec. 12, 2001 (JP) 2001-378999

(51) Int. Cl. B05D 3/00

(52) U.S. Cl. 427/532; 427/162

(57) ABSTRACT

A main object of the present invention is to provide a process for manufacturing a pattern forming body which can coat a functional part-forming coating solution even when a nozzle discharging method is used at a high precision. The present invention attains the above object by providing a process for manufacturing a pattern forming body, which comprises: a charge-electrified pattern-forming process of forming a pattern comprising a charge-electrified region electrified with a charge and a charge-nonelectrified region electrified with no charge, on a substrate, and a functional part pattern-forming process of forming a pattern of a functional part by discharging and coating a functional part-forming coating solution on the charge-nonelectrified region by a nozzle discharging method.

### BACKGROUND OF THE INVENTION

1. Field of the Invention

The present invention relates to a process for manufacturing a pattern forming body which can be effectively utilized in a variety of functional elements such as an electroluminescent (hereinafter, abbreviated as EL in some cases) element and the like.

2. Description of the Related Art

In recent years, upon formation of a variety of functional elements such as a light-emitting layer of an EL element and a color filter, a method of forming a functional element by coating a functional part-forming coating solution in a pattern using a nozzle discharging method, for example, an ink jet method or the like is being studied.

Such the patterning method using a nozzle discharging method is excellent in the efficacy of utilizing a material as compared with patterning by the usual photolithography method, and has an advantage of being better in a precision aspect as compared with patterning by a printing method.

However, in such the nozzle discharging method such as an ink jet method and the like, there is a problem in the straight going property of a discharged coating solution in some cases and, when a precision in the straight going property is worse, a functional part-forming coating solution is coated outside the region to be coated and, thus, there is a problem that high precision patterning becomes difficult, and a yield is reduced due to troubles such as color mixing and the like.

### SUMMARY OF THE INVENTION

The main object of the present invention is to provide a process for manufacturing a pattern forming body which can coat a functional part-forming coating solution at a better precision even when a nozzle discharging method is used.

In order to attain the aforementioned object, a process for manufacturing a pattern forming body which comprises a charge-electrified pattern-forming process, of forming a charge-electrified region electrified with a charge and a charge-nonelectrified region electrified with no charge on a substrate, and a functional part pattern-forming process, of forming a functional part pattern on the above mentioned charge-nonelectrified region by discharging and coating a functional part-forming coating solution by a nozzle discharging method, is provided.

According to the present invention, since a charge is electrified on a charge-electrified region as mentioned, a liquid droplet of the discharged functional part-forming coating solution goes straight toward a charge-nonelectrified region in between charge-electrified regions. Thereby, it becomes possible to form a high precision pattern.

In the present invention, it is preferable that a functional part-forming coating solution discharged by the above mentioned nozzle discharging method is electrified with the same kind of charge as that of the above mentioned charge-electrified region. Like this, by electrification of a droplet of a functional part-forming coating solution, discharged by a nozzle discharging method, with the same kind of charge as that of a charge-electrified region, a higher repulsion is generated in a droplet from a charge-electrified region and, as a result, a better straight going property of a droplet toward a charge-nonelectrified region is obtained, and it becomes possible to manufacture a higher precision pattern at a higher yield.

In the present invention, it is preferable that the nozzle discharging method is an ink jet method because the ink jet method is excellent in the efficacy of utilizing a material and is advantageous in the cost.

In the present invention, the process of forming a charge-electrified pattern may comprise; a process of forming a photocatalyst-containing layer, comprising at least a photocatalyst and a binder, and also having the wettablity changing such that a contact angle between water is reduced by irradiation of the energy, on a substrate; a process of forming a pattern comprising a water-repellent region and a hydrophilic region by irradiating energy to the photocatalyst-containg layer in a pattern; and a process of electrifying the water-repellent region with a charge.

Like this, when a method of forming a pattern comprising a charge-electrified region and a charge-nonelectrified region is used with a photocatalyst-containing layer, by simply forming a photocatalyst-containing layer, performing pattern exposure and performing electrification treatment, it becomes possible to form a charge-electrified region and a charge-nonelectrified region. Like this, since a pattern comprising a charge-electirified region and a nonelectrified region can be formed by pattern exposure, a high precision pattern can be obtained. In addition, a pattern comprising a charge-electrified region and a charge-nonelectrified region can be formed by simply performing pattern exposure and electrification treatment, the present method has the advantage in process.

In the present invention, it is preferable that the energy to be irradiated to the photocatalyst-containing layer is the light containing the ultraviolet-ray. The energy to be irradiated to the photocatalyst-containing layer may be any energy as long as it can change the wettability of the photocatalyst-containing layer. However, since the energy can be irradiated by a generally-used simple apparatus, it is preferable that the light containing ultraviolet-ray is used in the present invention.

In the present invention, it is preferable that the photocatalyst-containing layer contains fluorine, and the photocatalyst-containing layer is formed so that the fluorine content on the surface of the photocatalyst-containing layer is reduced by the action of the photocatalyst upon irradiation of the photocatalyst-containing layer with the energy, as compared with before energy irradiation. In the present invention, a region irradiated with the energy is made to be a hydrophilic region and a region not irradiated with the energy is made to be a water-repellent region. And, since it is necessary to electrify a water-repellent region, it is preferable that a large amount of fluorine is contained in a water-repellent region and, since it is necessary that a functional part-forming coating solution added dropwise is easily extended in a hydrophilic region, it is preferable the fluorine content is small.

In the present invention, it is preferable that the photocatalyst is 1 kind or 2 or more kinds of material (s) selected from titanium dioxide (TiO₂), zinc oxide (ZnO), tin-oxide (SnO₂), strontium titanate (SrTiO₃), tungsten oxide (WO₃), bismuth oxide (Bi₂O₃) and iron oxide (Fe₂O₃). Furthermore, it is preferable that, inter alia, the photocatalyst is titanium dioxide (TiO₂). Since titanium dioxide has the high band gap energy, it is effective as a photocatalyst, it is chemically stable and has no toxicity, and it can be easily obtained.

In the present invention, it is preferable that the photocatalyst-containing layer is such that a contact angle of a part not irradiated with the energy to water is greater than that of a part irradiated with the energy to water by one degree or greater. When a difference in contact angles is of this magnitude, patterning can be performed upon adding of a functional part-forming coating solution dropwise on a hydrophilic region.

In the present invention, it is preferable that the binder is organopolysiloxane which is a hydrolysis-condensate or co-hydrolysis-condensate of 1 kind or 2 or more kinds of silicon compound(s) represented by YₙSiX₍₄₋ₙ₎ (wherein Y denotes an alkyl group, a fluoroalkyl group, a vinyl group, an amino group, a phenyl group or an epoxy group, X denotes an alkoxyl group or harogen, and n is an integer of 0-3).

The organopolysiloxane is preferable in that a binder contained in a photocatalyst-containing layer requires such the energy that is not degraded by the action of a photocatalyst, and in that a binder itself preferably manifests a change in the wettability of a photocatalyst-containing layer by the action of a photocatalyst.

In the present invention, the process of forming the charge-electrified pattern may comprise a process of forming a pattern comprising an electrode layer region and an insulating layer region, and a process of electrifying the insulating layer region with a charge. Like this, when a pattern comprising an electrode layer region and an insulating layer region is formed, it becomes possible to form easily the pattern comprising a charge-electrified region and a charge-nonelectrified region by performing electrification treatment thereto.

In the present invention, it is preferable that the insulation layer region is formed so as to protrude from the electrode layer region. If the insulation layer region is formed so as to protrude from the electrode layer region, when the ink is discharged to the electrode layer region by a nozzle discharging method, it becomes possible to coat a functional part-forming coating solution on the electrode layer region which is a region to be coated, at a high precision and, thus, a higher precision functional element is obtained.

In the present invention, it is preferable, upon coating by discharge of the functional part-forming coating solution by the nozzle discharging method, voltage is applied to the electrode layer region with a different kind of charge from that to be electrified on the insulating layer region. Whereby, the droplets of a functional part-forming coating solution, electrified by voltage applied to the electrode layer region, can be attracted to the electrode layer region. As a result, it becomes possible to improve the straight going property of the droplet of a functional part-forming coating solution, and a higher precision functional element can be formed.

Further, the present invention provides a process for manufacturing an EL element which comprises; a process of forming a photocatalyst-containing layer comprising at least a photocatalyst and a binder and also having the wettability changing such that a contact angle between water is reduced by irradiation of the energy, on a substrate having an electrode layer; a process of forming a pattern comprising a water-repellent region and a hydrophilic region by irradiating energy to the photocatalyst-containing layer in a pattern; a process of electrifying the water-repellent region with a charge; and a process of forming a pattern of an organic EL layer by discharging and coating an organic EL layer-forming coating solution by a nozzle discharging method to the abovementioned water-repellent region.

In the present invention, since the water-repellent region is electrified as described above, the organic EL layer-forming coating solution is assuredly added dropwise to a hydrophilic region, and a high precision pattern of an organic EL layer can be obtained. Therefore, the quality of the finally obtained EL element can be improved.

In this case, it is preferable that the organic EL layer-forming coating solution is electrified with the same kind of charge as that of the water-repellent region. The organic EL layer-forming coating solution is assuredly added dropwise to a hydrophilic region by repulsion force of a charge and, as a result, it becomes possible to manufacture a high precision pattern at a high yield.

In the present invention, it is preferable that an insulating layer, formed so as to cover an edge part of the electrode layer and a non-light-emitting part of an EL element, is formed on a substrate having the electrode layer, and voltage is applied to the electrode layer with a different kind of charge from that of the water-repellent region upon coating by discharge of the organic EL layer-forming coating solution by the nozzle discharging method. Whereby, a part on which no insulation layer is formed, can attract the droplets of an organic EL layer-forming coating solution electrified with voltage applied to an electrode layer. As a result, it becomes possible to improve the straight going property of a droplet of an organic EL layer-forming coating solution, and a higher precision pattern of an organic EL layer can be manufactured in the state where it is less disadvantageous.

The present invention also provides a process for manufacturing an EL element which comprises; a process of forming a pattern comprising an electrode layer and an insulating layer on a substrate, having an electrode layer formed in a pattern by forming an insulation layer so as to cover an edge part of the electrode layer and a non-light-emitting part of an organic EL layer; a process of electrifying the insulating layer with a charge, and a process of forming pattern of an organic EL layer by discharging and coating an organic EL layer-forming coating solution on the electrode layer by a nozzle discharging method.

In the present invention, since a pattern of an electrode layer and an insulating layer is formed like this, it becomes possible to easily electrify an insulating layer, whereby, it becomes possible to assuredly add an organic EL layer-forming coating solution dropwise to an electrode layer.

In the present invention, it is preferable that the insulating layer is formed so as to protrude from the electrode layer. Considering formation by adding an organic EL layer-forming coating solution dropwise by a nozzle discharging method, the organic EL layer can be formed at a high precision without forcing the added-dropwise organic EL layer-forming coating solution out to the insulating layer side by partitioning an end of the electrode with a protruded insulating layer.

In the present invention, it is preferable that the organic EL layer-forming coating solution is electrified with the same kind of charge as that of the insulating layer. The organic EL layer-forming coating solution is added dropwise to the electrode layer region more precisely by repulsion force of a charge and, as a result, it becomes possible to manufacture a high precision pattern at a high yield.

In the present invention, it is preferable that voltage is applied to the electrode layer with a different kind of charge from that of the insulating layer upon discharging and coating of the organic EL layer-forming coating solution by the nozzle discharging method. A droplet of an organic EL layer-forming coating solution, electrified with voltage applied to an electrode layer, can be attracted. As a result, it becomes possible to improve the straight going property of the droplet of the organic EL layer-forming coating solution, and it becomes possible to manufacture a higher precision pattern of an organic EL layer in the state where it is less disadvantageous.

In the present invention, it is preferable that the nozzle discharging method is an ink jet method because the ink jet method is excellent in the efficacy of utilizing a material and is advantageous in the cost.

In the present invention, it is preferable that the organic EL layer is a light-emitting layer. For example, in order to obtain a full color EL element, at least three kinds of patterning of a light-emitting layer are required, and advantages of the present invention can be utilized effectively.

The present invention also provides a process for manufacturing a color filter, which comprises; a process of forming a phtocatalyst-containing layer comprising at least a photocatalyst and a binder and also having the wettability changing such that a contact angle between water is reduced by irradiation of the energy on a transparent substrate; a process of forming a pattern comprising a water-repellent region and a hydrophilic region by irradiating the photocatalyst-containing layer with the energy in a pattern; a process of electrifying the water-repellent region with a charge, and a process of forming pattern of a pixel part by discharging and coating a pixel part-forming coating solution on the hydrophilic region by a nozzle discharging method. In the present invention, since the water-repellent region is electrified as described above, the pixel part-forming coating solution is assuredly added dropwise to the hydrophilic region and, as a result, it becomes possible to manufacture a high precision color filter having no disadvantage such as color mixing and the like.

In this case, it is preferable that the pixel part-forming coating solution is electrified with the same kind of charge as that of the water-repellent region. When electrified with the same kind of charge, since the water-repellent region and the pixel-forming coating solution repel each other, it becomes possible to coat the pixel part-forming coating solution in the hydrophilic region more accurately, and a color filter can be manufacture at a high precision.

Further, in the present invention, it is preferable that the nozzle discharging method is an ink jet method. The ink jet method is excellent in efficacy of utilizing a material, and is advantageous in the cost.

According to the present invention, since a charge-electrified region is electrified with a charge, a droplet of the discharged functional part-forming coating solution goes straight toward the charge-nonelectrified region. Whereby, such the effect is exerted that it becomes possible to form a high precision pattern.

### BRIEF DESCRIPTION OF THE DRAWINGS

FIGS. 1A to 1F are process views showing one example of a process for manufacturing a pattern forming body of the present invention.

FIGS. 2A to 2E are process views showing another example of a process for manufacturing a pattern forming body of the present invention.

### DESCRIPTION OF THE PREFERRED EMBODIMENTS

1. A process of Manufacturing a Pattern Forming Body

First, a process of manufacturing a pattern forming body of the present invention will be explained in detail. The process for manufacturing a pattern forming body of the present invention comprises a charge-electrified pattern-forming process of forming a pattern comprising a charge-electrified region electrified with a charge and a charge-nonelectrified region electrified with no charge on a substrate, and a functional part pattern-forming process of forming a functional part pattern by discharging and coating a functional part-forming coating solution onto the charge-nonelectrified region by a nozzle discharging method.

Like this, in the process for manufacturing a pattern forming body of the present invention, since a substrate side is electrified in a pattern in advance upon formation of a functional part in a pattern by discharging and coating a functional part-forming coating solution by a nozzle discharging method, a droplet of a functional part-forming coating solution discharged by a nozzle discharging method go straight toward a charge-nonelectrified region electrified with no charge. Whereby, it becomes possible to maintain the straight going property of a droplet, which has been a problem upon formation of a high precision pattern by the previous nozzle discharging method, and it becomes possible to manufacture a high precision pattern at a high yield.

A pattern in the present invention refers to a variety of designs such as figure, picture, circuit, letter and the like, being not limiting.

The process for manufacturing a pattern forming body of the present invention will be explained below by classifying into a charge-electrified pattern-forming process and a functional part pattern-forming process.

(1) Charge-Electrified Pattern-Forming Process

The charge-electrified pattern-forming process is a process of forming a pattern comprising a charge-electrified region electrified with a charge and a charge-nonelectrified region electrified with no charge on a substrate as described above and, in the present invention, this charge-electrified pattern-forming process can be classified into two embodiments. Therefore, for the following explanation, the charge-electrified pattern-forming process is classified into two embodiments, that is, a first embodiment and a second embodiment.

### \mathring{1} First Embodiment

The first embodiment of the charge-electrified pattern forming-process in the present invention comprises; a process of forming a photocatalyst-containing layer comprising at least a photocatalyst and a binder and also having the wettability changing such that a contact angle between water is reduced by irradiation of the energy; a process of forming a pattern comprising a water-repellent region and a hydrophilic region by irradiating energy to the photocatalyst-containing layer in a pattern; and a process of electrifying the water-repellent region with a charge.

Like this, in the present embodiment, since a pattern comprising a water-repellent region and a hydrophilic region is formed on the surface of a photocatalyst-containing layer and, thereafter, a water-repellent region is electrified with a charge, when a functional part-forming coating solution is discharged and coated on a hydrophilic region by a nozzle discharging method, a functional part-forming coating solution goes straight toward a hydrophilic region and is easily attached to the region and, as a result, high precision patterning of a functional part becomes possible.

First, the present embodiment will be explained briefly by using drawings.

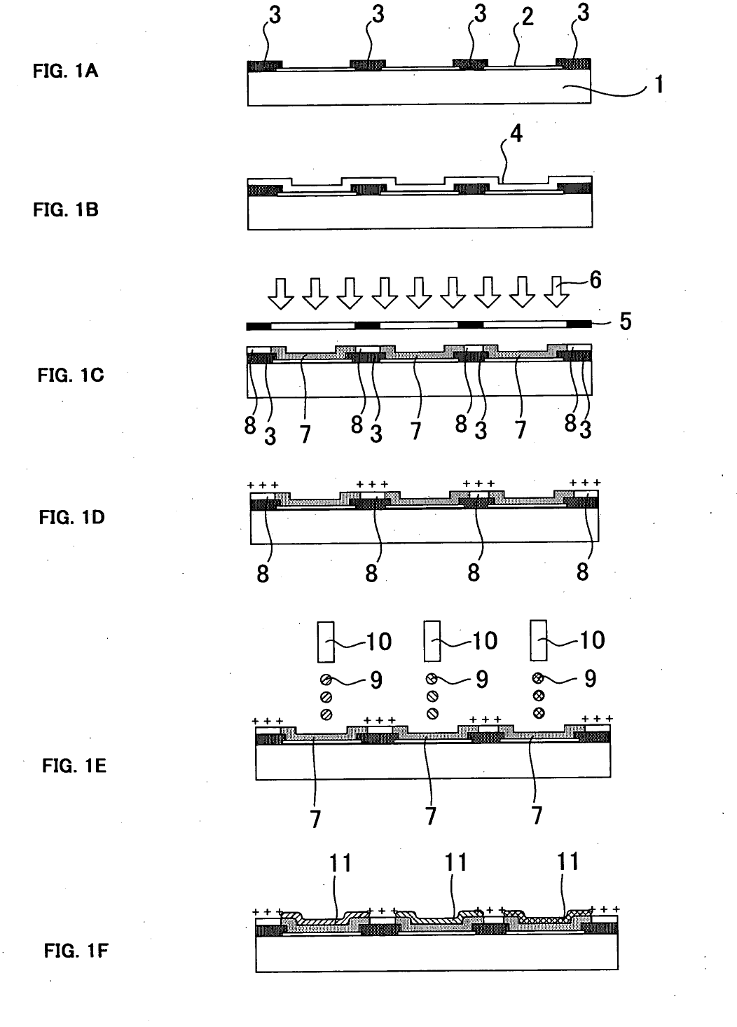

FIG. 1 schematically shows an example where a functional element is an EL element, as one example of the present embodiment. In this manufacturing process, first, after a transparent electrode layer 2 is formed on a substrate 1, an insulating layer 3 is formed on a position partitioning an opening of a light-emitting layer. And, a photocatalyst-containing layer 4 is formed on a substrate 1 on which a transparent electrode 2 and an insulating layer 3 are formed like this (A. Photocatalyst-containing layer forming process FIGS. 1(A) and 1(B)).

Then, the substrate 1 on which this photocatalyst-containing layer 4 is formed, is irradiated with the ultraviolet light 6 in a pattern using a photomask 5 in this example (B. Pattern exposing process FIG. 1(C)). Whereby, a part which has been irradiated with the ultraviolet light 6 becomes a hydrophilic region 7, and a non-irradiated part becomes a water-repellent region 8. This water-repellent region 8 is usually formed on an insulating layer 3 formed at a position partitioning an opening of the light-emitting layer.

Further, the water-repellent region 8 is electrified to form a charge-electrified pattern. Herein, a positively electrified example is shown (C. Electrification treatment process FIG. 1(D)).

Then, materials and methods used will be explained in detail per each process mentioned above.

A. Photocatalyst-Containing Layer Forming Process

In the present embodiment, a photocatalyst-containing layer forming process is first performed in which a photocatalyst-containing layer having the wettability changing such that a contact angle between water is reduced by irradiation of the energy is formed on substrate. The photocatalyst-containing layer and the substrate to be used herein will be explained below.

(Photocatalyst-Containing Layer)

The photocatalyst-containing layer used in the present embodiment is a layer in which the wettability is changed such that a contact angle between water is reduced by irradiation of the energy, and comprises at least a photocatalyst and a binder. Like this, by providing a photocatalyst-containing layer in which the wettability is changed such that a contact angle between water is reduced by exposure to the light (meaning that not only the light is irradiated but also the energy is irradiated in the present embodiment), the wettability can be easily changed by performing irradiation of the energy in a pattern, and a hydrophilic region having a small contact angle between water can be obtained, it becomes possible to coat a functional part-forming coating solution only on this hydrophilic region. In addition, in a water-repellent region, since a functional group having a high electric resistance such as fluorine and alkyl group is exposed on the surface, an electric resistance is generally high. Therefore, by performing electrification treatment on this water-repellent region as described below, the region can be electrified with a charge and, as a result, the going straight property of a functional part-forming coating solution discharged by a nozzle discharging method can be improved. As the energy in this case, the light containing the ultraviolet light is usually used.

A hydrophilic region herein refers to a region having a small contact angle between water and refers to a region having a good wettability to a functional part-forming coating solution for forming a functional part described below. In addition, a water-repellent region refers to a region having a large contact angle between water, and a region having a poor wettability to a functional part-forming coating solution for forming a functional part described below.

The photocatalyst-containing layer in the present embodiment is preferably a photocatalyst-containing layer in which a contact angle between water in a part not irradiated with the energy is a greater contact angle than that between water in a part irradiated with the energy by one degree or greater and, more preferably, a photocatalyst-containing layer in which the above difference is 5 degree or greater, most preferably 10 degree or greater is used.

When a difference between a contact angle between water in a part not irradiated with the energy and a contact angle between water in a part irradiated with the energy is less than a prescribed range, it becomes difficult to coat a functional part-forming coating solution in a pattern by utilizing a difference in the wettability, and it becomes difficult to form a functional part in a pattern.

As a specific contact angle between water in such the photocatalyst-containing layer, it is preferable that a contact angle between water in a part not exposed to the light is 30 degrees or greater, particularly 60 degrees or greater, inter alia, 90 degrees or greater. A photocatalyst-containing layer having such the contact angle between water is suitably used. That is, a part not exposed to the light is a part for which the water repellency is required in the present embodiment. Therefore, when a contact angle between water is small, the water repellency is not sufficient, there is a possibility that a functional part-forming coating solution described below remains also in a part requiring no such the solution, and a precision of a pattern forming body may be reduced.

In addition, as a contact angle when a photocatalyst-containing layer is exposed to the light, specifically, a photocatalyst-containing layer having a contact angle of less than 30 degrees, particularly 20 degrees or smaller, inter alia, 10 degrees or smaller is preferable. When a contact angle between water in a part exposed to the light is high, there is a possibility that extension of a functional part-forming coating solution for forming a functional part is inferior in this part, the solution is not extended throughout a region on which a functional part is to be formed and, as a result, the pattern precision of the resulting functional part is reduced and, thus, quality of the final product of a functional element is deteriorated.

A contact angle between water herein is obtained by measuring a contact angle between water with a contact angle measuring equipment (CA-Z type: manufactured by Kyowa Interface Science Co., LTD.) (30 seconds after addition dropwise of a water droplet from a microsyringe).

In addition, as described below, since a water-repellent region not exposed to the light has to be electrified in an electrification treatment process as described below, it is preferable that a surface resistance is large to an extent. Specifically, it is preferable that a photocatalyst-containing layer is electrified in a range of 30V to 2000V, more preferably in a range of 30V to 1000V at corona electrification 5 k.

On the other hand, in the electrification treatment process, it is preferable that a hydrophilic region exposed to the light is not electrified with a charge. Therefore, it is preferable that a photocatalyst-containing layer is electrified in a range of 0V to 30V, more preferably in a range of 0V to 10V at corona electrification 5 k by performing the aforementioned exposure to the light.

It is preferable that the photocatalyst-containing layer comprises at least a photocatalyst and a binder. By adopting such the layer, it becomes possible to heighten a critical surface tension by the action of a photocatalyst by irradiation of the energy, and a contact angle between water can be reduced.

Although the mechanism of action of a photocatalyst, a representative of which is titanium oxide as described below, in such the photocatalyst-containing layer is not necessarily clear, it is considered that a carrier generated by irradiation of the light influences on a change in the chemical structure of an organic material by a direct reaction with an adjacent compound, by oxygen, or by an active oxygen species generated in the presence of water.

The photocatalyst-containing layer used in the present embodiment can change the wettability of a part irradiated with the energy with a photocatalyst by using the action of oxidation, degradation, or the like of an organic group as a part of a binder or an additive and make the part hydrophilic, generating a great difference in the wettability between an unirradiated part. Therefore, by enhancing the receiving property (hydrophilicity) and the repellent property (water-repellency) to a functional part-forming coating solution for forming a functional part, there can be obtained a pattern forming body which has a better precision and is advantageous in the cost.

In addition, when such the photocatalyst-containing layer is used in the present embodiment, the photocatalyst-containing layer may be formed so that this photocatalyst-containing layer comprises at least a photocatalyst and fluorine, and the fluorine content on the surface of this photocatalyst-containing layer is reduced by the action of the photocatalyst as compared with before irradiation of the energy upon irradiation of the photocatalyst-containing layer with the energy.

In the pattern forming body having such the features, a pattern comprising a part containing a small amount of fluorine can be easily formed by irradiation of the energy in a pattern. Herein, fluorine has the extremely low surface energy and, for that reason, the surface of a substance containing a large amount of fluorine has a smaller critical surface tension. Therefore, a critical surface tension of a part having a smaller amount of fluorine becomes greater in comparison with a critical surface tension of the surface of a part having a large amount of fluorine. This means that a part having a smaller amount of fluorine becomes a hydrophilic region as compared with a part having a large amount of fluorine. Therefore, formation of a pattern comprising a part having smaller fluorine content than that of the surrounding surface leads to formation of a pattern of a hydrophilic region in a water-repellent region.

Therefore, when such the photocatalyst-containing layer is used, since a pattern of a hydrophilic region can be easily formed in a water-repellent region by irradiation with the energy in a pattern, it becomes possible to easily coat a functional part-forming coating solution for forming a functional part only on this hydrophilic region, and a high precision pattern forming body can be obtained.

In addition, if the fluorine content on the surface of a water-repellent region can be increased and the fluorine content of a hydrophilic region can be decreased like this, it becomes possible to maintain a surface resistance of a water-repellent region high as described above and, at the same time, it becomes possible to considerably reduce a surface resistance of a hydrophilic region and, thus, the effect and advantage of the present embodiment due to electrification can be exerted effectively.

It is preferable that the fluorine content in a hydrophilic region having the low fluorine content which has been formed by irradiation of the energy is 10 or smaller, preferably 5 or smaller, particularly preferably 1 or smaller, stating the fluorine content of a part not irradiated with the energy to be 100.

By adopting such the range, a great difference in the hydrophilicities and the electrifications between a part irradiated with the energy and a part not irradiated with the energy can be caused. Therefore, it becomes easy to electrify such the photocatalyst-containing layer in a pattern, and at the same time, by coating a functional part-forming coating solution on such the photocatalyst-containing layer, it becomes possible to form a functional part precisely only on a hydrophilic region having the reduced fluorine content. Therefore, based on these two effects, a pattern forming body can be obtained at a high precision. This reduction rate is based on weight.

For measuring the fluorine content in such the photocatalyst-containing layer, a variety of methods which are normally conducted can be used, for example, such as X-ray Photoelectron Spectroscopy (also termed ESCA (Electron Spectroscopy for Chemical Analysis)), Fluorescent X-ray Analysis, Mass Analysis and the like. The method is not particularly limited as far as it can quantitatively measure an amount of fluorine on the surface.

Examples of the photocatalyst used in present embodiment include titanium dioxide (TiO₂), zinc oxide (ZnO), tin oxide (SnO₂), strontium titanate (SrTiO₃), tungsten oxide (WO₃), bismuth oxide (Bi₂O₃) and iron oxide (Fe₂O₃) which are known as a photosemiconductor, and 1 kind, or 2 or more kinds selected from them can be used by mixing.

In the present embodiment, in particular, titanium dioxide is suitably used because it has the high band gap energy, is chemically stable and has no toxicity and is easily obtained. Titanium oxide has anatase type and rutile type, both types can be used in the present embodiment, anatase type titanium oxide being preferable. Anatase type titanium oxide has an excitation wavelength of 380 nm or shorter.

Examples of such the anatase type titanium oxide include hydrochloric acid-deflocculated anatase type titania sol (STS-02 (average particle diameter 7 nm) manufactured by Ishihara Sangyo Kaisha, Ltd., ST-K01 manufactured by Ishihara Sangyo Kaisha, Ltd.), nitric acid-deflocculated anatase type titania sol (TA15 (average particle diameter 12 nm) manufactured by Nissan Chemical Industries, Ltd.).

As a particle diameter of a photocatalyst grows smaller, a photocatalytic reaction occurs more effectively, being preferable. An average particle diameter of 50 nm or smaller is preferable. It is particularly preferable to use a photocatalyst having an average particle diameter of 20 nm or smaller. In addition, as a particle diameter of a photocatalyst is smaller, the surface crudeness of a formed photocatalyst-containing layer becomes smaller, being preferable. When a particle diameter of a photocatalyst exceeds 100 nm, the center line average surface crudeness in a photocatalyst-containing layer becomes cruder, the water-repellency of an unexposed part of a photocatalyst-containing layer is lowered, and manifestation of the hydrophilicity of an exposed part becomes insufficient, being not preferable.

In the present embodiment, it is preferable that the aforementioned titanium dioxide is used as a photocatalyst. It is preferable that the content of fluorine contained in a photocatalyst-containing layer when titanium dioxide is used like this is such that fluorine (F) element is contained on the surface of a photocatalyst-containing layer at a ratio of fluorine (F) element of 500 or more, more preferably 800 or more, particularly preferably 1200 or more as quantified by analysis by X-ray photoelectron spectroscopy, stating titanium (Ti) element to be 100.

Since it becomes possible to sufficiently reduce a critical surface tension on a photocatalyst-containing layer by inclusion of florine (F) in a photocatalyst-containing layer to this extent, the water-repellency on the surface can be retained, whereby, a difference in the wetability between a hydrophilic region on the surface at a pattern part where the fluorine content is reduced by irradiation of the energy in a pattern can be increased, a high precision pattern forming body can be obtained, and the quality of the finally obtained functional element can be improved In addition, by inclusion of fluorine to this extent, a surface resistance can be retained grater, and electrification treatment at an electrification treatment process described below becomes easy.

Further, in such the pattern forming body, it is preferable that the fluorine content in a hydrophilic region formed by irradiation of the energy in a pattern is such that fluorine (F) element is contained at a ratio of 50 or smaller, more preferably 20 or smaller, particularly preferably 10 or smaller, stating the titanium (Ti) element to be 100.

When the content of fluorine in a photocatalyst-containing layer can be decreased to this extent, the sufficient hydrophilicity for attaching a functional part-forming coating solution for forming a functional part and for sufficiently extending the solution in a region can be obtained, it becomes possible to form a pattern of a functional part-forming coating solution at a better precision due to a difference in the wettability between the water-repellency of the part unirradiated with the energy, and a functional element having the better quality can be obtained. In addition, since it becomes possible to increase a difference in the electrifying property between a water-repellent region, electrification treatment as described below becomes easy.

In the present embodiment, a binder employed in a photocatalyst-containing layer preferably has the high bonding energy that a main skeleton is not degraded by the photoexcitation by the above mentioned photocatalyst, and examples thereof include; (1) organopolysiloxanes having the great strength obtained by hydrolysis and polycondensation of chloro- or alkoxysilane by a sol-gel reaction; (2) organopolysiloxanes cross-linked with a reactive silicone excellent in the water-repellency or the oil-repellency, and the like.

In the case of the aforementioned (1), the organopolysiloxane is preferably an organopolysiloxane which is hydrolysis-condensate or cohydrolysis-condensate of 1 or 2 or more silicone compounds represented by the following general formula:
YₙSiX₍₄₋ₙ₎
wherein Y denotes an alkyl group, a fluoroalkyl group, a vinyl group, an amino group, a phenyl group or an epoxy group, X denotes an alkoxyl group, an acetyl group or halogen, and n is an integer of 0-3. It is preferable that the number of carbons of a group represented by Y is in the range of 1-20, and it is preferable that an alkoxy group represented by X is a methoxy group, an ethoxy group, a propoxy group, or a butoxy group.

In addition, as the binder, particularly polysiloxane containing a fluoroalkyl group can be preferably used, and polysiloxanes known as a fluorine series silane coupling agent can be generally used.

By using such the polysiloxanes containing a fluoroalkyl group as the binder, the water-repellency at a part of a photocatalyst-containing layer unirradiated with the energy is greatly improved, and it becomes possible to considerably increase a surface resistance.

In addition, examples of reactive silicone of the (2) include compounds having a skeleton represented by the following general formula: 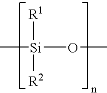
wherein n is an integer of 2 or more, and R¹ and R² are each substituted or unsubstituted alkyl, alkenyl, arryl or cyanoalkyl group having a carbon number of 1-10, and 40% or smaller of the whole at a mole ratio is vinyl, phenyl or halogenated phenyl. In addition, R¹ and R² are preferably a methyl group because the surface energy becomes minimum, and it is preferable that 60% or more at a mole ratio is a methyl group. In addition, the compounds have 1 or more reactive groups such as a hydroxyl group and the like in a molecular chain at a terminal of chain or a side chain.

Alternatively, a stable organosilicon compound which does not conduct a cross-linking reaction such as dimethylpolysiloxane together with the aforementioned organopolysiloxane may be mixed in a binder.

In the present embodiment, like this, a variety of binders such as polyorganosiloxane and the like can be used in a photocatalyst-containing layer. In the present embodiment, as described above, by inclusion of fluorine in a photocatalyst-containing layer containing such the binder and a photocatalyst and irradiating the layer with the energy in a pattern, fluorine on the surface of a photocatalyst-containing layer can be reduced, whereby, a hydrophilic region may be formed in a water-repellent region. Upon this, it is necessary that fluorine is contained in a photocatalyst-containing layer and, as a method of inclusion of fluorine in a photocatalyst-containing layer containing such the binder, there are a method of bonding a fluorine compound to a binder usually having the high bonding energy, with the relatively weak bonding energy, a method of mixing a fluorine compound bound with the relatively weak bonding energy in a photocatalyst-containing layer, and the like. By introducing fluorine by such the method, when irradiated with the energy, a fluorine bonding site having the relatively small bonding energy is first degraded by the action of a photocatalyst, whereby, fluorine can be removed from a photocatalyst-containing layer.

As the aforementioned first method, that is, a method of bonding a fluorine compound to a binder having the high bonding energy, with the relatively weak bonding energy, there is a method of introducing a fluoroalkyl group as a substituent into the aforementioned organopolysiloxane.

In addition, in the method shown in the (2), organopolysiloxane is obtained by cross-linking a reactive silicone excellent in the water-repellency or the oil-repellency and, also in this case, it is possible that fluorine is contained in a photocatalyst-containing layer by adopting a substituent containing fluorine such as a fluoroalkyl group as R¹ or R² or the both in the above general formula, and since a part of a fluoroalkyl group having the smaller bonding energy than that of a siloxane linkage is degraded when irradiated with the energy, the content of fluorine on the surface of the photocatalyst-containing layer can be reduced by irradiation with the energy.

On the other hand, as an example of the latter, that is, a method of introducing a fluorine compound bound with the weaker energy than the bonding energy of a binder, for example, there is a method of introducing a low-molecular weight fluorine compound, specifically, a method of mixing a fluorine series surfactant. In addition, as a method of introducing a high-molecular weight fluorine compound, there is a method of mixing a fluorine resin having the high compatibility with a binder resin.

In the present embodiment, in addition to the aforementioned photocatalyst and binder, a surfactant can be contained in a photocatalyst-containing layer. Specifically, examples thereof include hydrocarbon-series such as each series of NIKKOL BL, BC, BO and BB manufactured by Nikko Chemicals Co., Ltd., and fluorine series such as ZONYL FSN and FSO manufactured by DuPont, Surfuron S-141 and 145 manufactured by Asahi Glass Company, Megafack F-141 and 144 manufactured by Dainippon Ink and Chemicals, Incorporated, Futagent F-200 and F251 manufactured by Neos, Unidyne DS-401 and 402 manufactured by DAIKIN INDUSTRIES, Ltd., Furolard FC-170 and 176 manufactured by 3M, and the like, or silicon series nonionic surfactants. In addition, cationic series surfactants, anionic series surfactants, and amphoteric surfactants may be used.

Alternatively, in addition to the aforementioned surfactants, the photocatalyst-containing layer may contain oligomers, polymers and the like of polyvinyl alcohol, unsaturated polyester, acryl resin, polyethylene, diallyl phthalate, ethylene-propylene-diene monomer, epoxy resin, phenol resin, polyurethane, melamine resin, polycarbonate, polyvinyl chloride, polyamide, polyimide, styrene-butadiene rubber, chloroprene rubber, polypropylene, polybutyrene, polystyrene, polyvinyl acetate, polyester, polybutadiene, polybenzimidazole, polyacrylonitrile, epichlorohydrin, polysulfide, polyisoprene and the like.

The content of a photocatalyst in a photocatalyst-containing layer may be set in a range of 5%-60% by weight, preferably in a range of 20%-40% by weight. In addition, it is preferable that a thickness of a photocatalyst-containing layer is in a range of 0.05 μm-10 μm.

The aforementioned photocatalyst-containing layer can be formed by dispersing a photocatalyst and a binder, if necessary, together with other additives in a solvent to prepare a coating solution, and coating this coating solution. As a solvent to be used, organic solvents of an alcohol series such as ethanol, isopropanol and the like are preferable. Coating may be performed by the known coating methods such as spin coating, spray coating, dip coating, roll coating, bead coating and the like. When an ultraviolet ray curing type component is contained as a binder, a photocatalyst-containing layer can be formed by performing curing treatment by irradiation of ultraviolet-ray.

(Substrate)

In the present embodiment, the aforementioned photocatalyst-containing layer is formed on a substrate. Examples of such the substrate include glass, metal such as aluminium and alloy thereof, plastic, woven fabric, nonwoven fabric and the like depending on the use of the resulting pattern forming body and the use of a functional element obtained by the pattern forming body. In the present embodiment, a transparent substrate is preferably used as a substrate because it is suitable for an EL element and a color filter which are a most suitable application example of the resulting pattern forming body. This transparent substrate is not particularly limited, but transparent rigid materials having no flexibility such as quartz glass, Pyrex (registered trade mark) glass, synthetic quartz plate and the like, and transparent flexible materials having the flexibility such as transparent resin film, optical resin plate and the like can be used.

In addition, as in an example shown in the aforementioned FIG. 1, an electrode layer or an insulating layer may be formed on a substrate and, in an examples of a color filter, a substrate on which a black matrix is formed in advance may be used.

B. Pattern Exposing Process

Then, a pattern exposing process of irradiating a substrate on which a photocatalyst-containing layer is formed, with the energy in a pattern to form patterns having the different wettabilities on a photocatalyst-containing layer will be explained. In a example shown in FIG. 1, this process corresponds to a process of irradiating a substrate 1, on which a photocatalyst-containing layer 4 is formed, with ultraviolet light 6 in a pattern using a photomask 5 (FIG. 1C).

In the present embodiment, the energy to be irradiated to a photocatalyst-containing layer is not particularly limited as far as it is the energy acting on a photocatalyst and, specifically, it is preferable that a light containing the ultraviolet light is used. The reason is as follows.

That is, photocatalysts used in the present embodiment have different wavelengths of the lights which initiate a catalytic reaction depending on the band gap thereof. For example, the light for cadmium sulfide is the visible light at 496 nm, the light for iron oxide is the visible light at 539 nm, and the light for titanium dioxide is the ultraviolet light at 388 nm. Therefore, whether the visible light or the ultraviolet light, any light may be used in the present embodiment. However, as described above, titanium dioxide is suitably used as a photocatalyst because it is effective as a photocatalyst due to the high band gap energy, is chemically stable and has no toxicity, and it is easily obtained. In this context, it is preferable that the light containing the ultraviolet light which initiates a catalytic reaction of this titanium dioxide. Specifically, it is preferable that the ultraviolet light in a range of 400 nm or shorter, more preferably in a range of 380 nm or shorter is contained.

As a source of such the light containing the ultraviolet light, there are a variety of ultraviolet ray sources such as mercury lamp, metal halide lamp, xenon lamp, excimer lamp and the like.

When pattern irradiation is necessary upon irradiation of the energy, pattern irradiation may be performed via a photomask using the aforementioned light source. As other method, a method of irradiating a delineation in a pattern using a laser such as excimer, YAG and the like may be used.

C. Electrification Treatment Process

In the present embodiment, after patterns having the different wettabilities such as a water-repellent region and a hydrophilic region are formed on the surface of a photocatalyst-containing layer by pattern exposure, an electrification treatment process is performed in order to electrify only this water-repellent region with a charge. An example shown in FIG. 1 corresponds to a process shown in FIG. 1D in which a water-repellent region 8 is electrified with a positive charge.

Examples of such the electrification treatment method include an electrification method by corona electrification of falling ions on the surface of a substrate using a corona electrode, a method of peeling-electrifying the surface by providing an insulating peeling-layer on the surface of a substrate, and peeling a peeling-layer from the substrate, a method of electrification by providing an opposite electrode and applying voltage to a substrate via a few μm to ten and a few μm air gap or an insulating intermediate layer.

In the present embodiment, it is preferable that an electrification method by corona electrification is used because a process is easy.

In the present embodiment, when the whole plane is electrified, only an unexposed part, that is, a water-repellent region of a photocatalyst-containing layer can be electrified in a pattern.

In addition, in the present embodiment, a method of electrification in a pattern may be used. For example, it becomes possible to perform pattern-like electrification by controlling voltage of a grid electrode by combining a corona electrode and a grid electrode.

In addition, electrification treatment of a water-repellent region in the present embodiment may be positive or negative electrification, being not particularly limited.

### \mathring{2} Second Embodiment

In the second embodiment of the charge-electrified pattern-forming process in the present invention, the charge-electrified pattern-forming process has a process of forming a pattern comprising an electrode layer region and an insulating layer region, and a process of electrifying the aforementioned insulating a layer region with a charge.

Like this, in the present embodiment, a pattern comprising an electrode layer region and an insulating layer region is formed and, thereafter, an insulating layer region is electrified with a charge. Therefore, when a functional part-forming coating solution is discharged by a nozzle discharging method and is coated on an electrode layer region, it allows a functional part-forming coating solution to go straight towards an electrode layer region and makes it easy to attach thereto and, as a result, high precision patterning for a functional part becomes possible.

Such the present embodiment will be explained by using drawings.

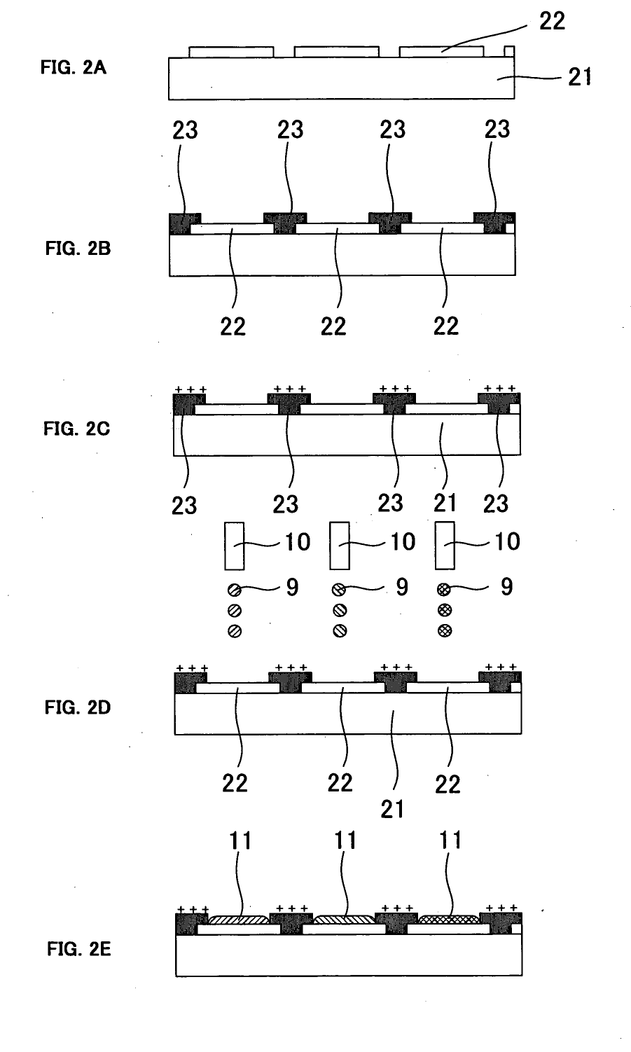

FIG. 2 schematically shows an example where a functional element is an EL element as one example of the present embodiment.

In this manufacturing process, first, a transparent electrode 22 is formed on a substrate 21 in a pattern, and thereafter, insulating layers 23 are formed in between the transparent electrodes 22 so as to cover the edge parts of the transparent electrodes 22 (A. Insulating layer region pattern-forming process, (FIGS. 2A and 2B)).

Further, a charge-electrified pattern is formed by electrifying the insulating layer 23. Herein, an example of electrification with a positive charge is shown (B. Electrification treatment process, FIG. 2C).

Then, materials and methods used will be explained in detail for each process.

A. Insulating Layer Region Pattern-Forming Process

The insulating layer region pattern-forming process in the present embodiment is a process of forming a pattern comprising an electrode layer region and an insulating layer region. A method of forming such the pattern may be, as shown in FIG. 2, a method of forming a pattern comprising an electrode layer region and an insulating layer region by forming an electrode layer in a pattern, and forming an insulating layer in a pattern so as to cover a part on which no electrode layer is formed and an edge part of an electrode layer, or may be a method of forming a pattern comprising an electrode layer region and an insulating layer region by forming an electrode layer on the whole plane and forming an insulating layer thereon in a pattern.

A method of patterning the aforementioned electrode layer and insulating layer is not particularly limited, but a photolithography method, a printing method and the like, which are generally used for patterning, are used.

Herein, an electrode layer region in the present embodiment refers to a region where an electrode layer is exposed on the surface, and an insulating layer region refers to a region where an insulating layer is exposed on the surface.

(Insulating Layer Region)

An insulating layer region used in the present embodiment is a region where an insulating layer is exposed on the surface as described above. A material which can be used in the insulating layer in this case is not particularly limited as far as it is a material having the insulating property to such an extent that electrification is possible. Specifically, it is preferable that a material having a specific resistance of 10⁶ Ω/cm or greater is used.

In the present embodiment, as also shown in FIG. 2B, it is preferable that an insulating layer region is formed protruding from an electrode layer region. By formation of an insulating region protruding from an electrode layer region like this, when a functional part-forming coating solution is coated by a nozzle discharging method and, thereafter, a coated functional part-forming coating solution is not mixed with an adjacent part, and a high precision functional element can be manufactured at a better yield.

Upon this, a height that an insulating layer region is protruded from an electrode layer region varies greatly depending on a precision of the resulting functional element, and also varies depending on a size of a droplet of an ink discharged by a nozzle discharging method, and it is preferable that the height is formed in a range of 0.10 μm to 100 μm, more preferably 0.1 μm to 10 μm.

(Electrode Layer Region)

The electrode layer region used in the present embodiment is a region where an electrode layer is exposed on the surface as described above. A material constituting this electrode layer is not particularly limited as far as it is a material having the conductivity to such an extent that it is not electrified when electrification treatment is performed in an electrification treatment process as described below, and the material may be transparent or opaque.

Specifically, it is preferable that a material having a specific resistance of 1 Ω/cm or smaller is used.

(Substrate)

Since the substrate used in the present embodiment is the same as that used in the aforementioned first embodiment, explanation is omitted herein.

B. Electrification Treatment Process

In the aforementioned first embodiment, a water-repellent region is electrified, but an insulation region is electrified in the present embodiment. Except for this point, the present process is the same as that explained for C. Electrification treatment process in the aforementioned first embodiment, therefore, explanation is omitted.

(2) Functional Part Pattern-Forming Process

Then, a functional part pattern-forming process in the present invention will be explained. The functional part pattern-forming process in the present invention is a process of forming a pattern of a functional part by discharging and coating a functional part-forming coating solution on the charge-nonelectrified region by a nozzle discharging method.

This process will be explained using FIG. 1 showing one example of the first embodiment of the aforementioned charge-electrified pattern-forming process. In FIG. 1D, a light-emitting layer forming coating solution (functional part-forming coating solution) 9 for forming a light-emitting layer (functional part) of an EL element (functional element) is coated on a hydrophilic region 7, the wettability of which has been improved by irradiation of ultraviolet light 6, by discharging to the hydrophilic region 7 with an ink jet apparatus (nozzle discharging apparatus) 10 (A. Functional part-forming coating solution coating process FIG. 1E). Upon this, since surrounding water-repellent regions are electrified, a light-emitting layer-forming coating solution 9 goes straight. In addition, since the surrounding is a water-repellent region also when attached to a hydrophilic region 7, there is little possibility that mixing with a coating solution of other regions is caused.

Finally, by solidifying this light-emitting layer-forming coating solution 9, a light-emitting layer 11 having a better precision is formed (FIG. 1F) and, if necessary, another organic EL layer is formed, and then an electrode layer and the like are formed to obtain an EL element (B Functional element completing process).

In addition, the present process is explained by using FIG. 2 showing one example of the second embodiment of the aforementioned charge-electrified pattern-forming process. In FIG. 2C, an insulating layer 23 is electrified, a light-emitting layer-forming coating solution (functional part-forming coating solution) 9 for forming a light-emitting layer (functional part) of an EL element (functional element) is coated on an electrode layer 22 by discharging to the electrode layer 22 with an ink jet apparatus (nozzle discharging apparatus) 10 (A. Functional part-forming coating solution coating process FIG. 2D). Upon this, since surrounding insulation layers 23 are electrified, a light-emitting layer-forming coating solution 9 goes straight. And, since surrounding insulation layers 23 are formed protruding when attached to an electrode layer 22, there is no possibility that color mixing with other regions is caused.

Finally, by solidifying this light-emitting layer-forming coating solution 9, a high precision light-emitting layer 11 is formed (FIG. 2E) and, if necessary, another organic EL layer is formed, and an electrode layer and the like are formed to obtain an EL element (B. Functional element completing process).

Each process of such the functional part pattern-forming process will be explained in detail below. The aforementioned charge-electrified pattern-forming process has two embodiments, but in the present process, fundamentally the same process is carried out in each embodiment, therefore, one embodiment will be explained.

A. Functional Part-Forming Coating Solution Coating Process

In the aforementioned electrification treatment process in the present invention, a functional part-forming coating solution coating process is performed in which a functional part-forming coating solution is coated on a charge-nonelectrified region by a nozzle discharging method. In FIG. 1, this process corresponds to a process of coating an organic EL layer-forming coating solution 9 on a part, the wettability of which has been improved by irradiation of ultraviolet light, with an ink jet apparatus 10 (FIG. 1E).

In the present invention, this functional part-forming coating solution is discharged by a nozzle discharging method. The reason is as follows: An object of the present invention is to improve the going straight property of a droplet of a functional part-forming coating solution discharged by a nozzle discharging method, and manufacture a higher precision pattern forming body and improve the quality of the resulting functional element.

Although there are a variety of methods as a nozzle discharging method used in the present invention, either of an ink jet method or a dispenser method is preferable in the present invention and, inter alia, since an ink jet method is suitably used in the case of large scale production, it can be said that the ink jet method which is advantageous in the cost is most preferable.

An ink jet apparatus used in this case is not particularly limited, but ink jet apparatuses using various methods such as a method of continuously jetting an electrified ink and controlling it with the magnetic field, a method of spraying the ink intermittently by piezoelectric element, a method of heating an ink and intermittently spraying the ink utilizing foaming thereof and the like can be used.

An object of a process for manufacturing a pattern forming body of the present invention is to improve the going straight property of a functional part-forming coating solution discharged by a nozzle discharging method by electrifying a water-repellent region or an insulating region upon coating of a functional part-forming coating solution as described above, whereby, a higher precision pattern is obtained. Upon this, when a discharged functional part-forming coating solution is electrified with the same kind charge as that of an electrified water-repellent region or an insulation layer region, the going straight property of a functional part-forming coating solution is further improved. Therefore, in the present invention, it is preferable to use a method or an apparatus which can electrify a functional part-forming coating solution with, the same kind of charge as that of an electrified water-repellent region or an insulation region, upon discharging of the coating solution.

Specifically, there can be contemplated indirect methods such as a method of electrifying a tip part or a whole discharging head upon discharging of functional part-forming coating solution, a method of induction-electrifying with a reverse charge by access to an electrified substance and the like, and direct methods of adding a surfactant promoting electrification or an insulating substance to a functional part-forming coating solution, mixing them, and subjecting the functional pert-forming coating solution itself to corona electrification or voltage application.

In the present embodiment, it is also considered that when a functional part-forming coating solution is discharged on an electrified substrate and the functional part-coating forming solution approaches the substrate, the functional part-forming coating solution is electrified with a reverse charge to that of a substrate by induced-electrification. Therefore, electrification of this functional part-forming coating solution is not essential in the present invention.

A functional part-forming coating solution used in the present invention varies greatly depending on the function of a functional part, a method of forming a functional part and the like, and for example, a composition which has not been diluted with a solvent, a representative of which is an ultraviolet-ray curing type monomer, and a liquid composition diluted with a solvent may be used. In addition, a functional part-forming coating solution having the low viscosity is particularly preferable because a pattern can be formed in a short period of time. However, in the case of a liquid composition diluted with a solvent, since increase in the viscosity and a change in the surface tension are caused due to volatilization of a solvent at pattern formation, it is desirable that a solvent is less volatile.

A functional part-forming coating solution used in the present invention may be a solution which becomes a functional part by arrangement by adding to a hydrophilic region or an electrode layer region, or may be a solution which becomes a functional part after arranged on a hydrophilic region or an electrode layer region, or after treated with a chemical, or treated with ultraviolet-ray, heat or the like. In this case, when a functional part-forming coating solution contains an ingredient which is cured by ultraviolet-ray, heat, electron beam or the like, as a binder, a functional part can be formed rapidly by curing treatment, being preferable.

In addition, it is preferable that a functional part-forming coating solution used in the present invention is electrifiable on the same grounds as aforementioned grounds such as improvement in the going straight property.

B. Functional Element Completing Process

In the present invention, as described above, a functional part-forming coating solution is coated by a nozzle discharging method in a functional part-forming coating solution coating process and, thereafter, a coated functional part-forming coating solution is cured or solidified to obtain a functional part and, if necessary, another member is formed to obtain a functional element.

In the present invention, a functional element refers to an element obtained by forming a functional part in a pattern by the aforementioned method.

The functionality specifically means various functions such as optical functions (light selective absorption, reflecting property, polarizing property, light selective transparency, non-linier optical property, luminescence such as fluorescence and phosphorescence, photochromic property etc.), magnetic functions (hard magnetism, soft magnetism, non-magnetism, magnetic permeability, etc.), electric or electronic functions (conductivity, insulating property, piezoelectric property, pyroelectric property, dielectric property, etc.), chemical functions (adsorbing property, desorption property, catalytic property, water absorbing property, ionic conductivity, redox property, electrochemical property, electrochromic property, etc.), mechanical functions (antifriction etc.), thermal functions (heat transferring property, adiabatic property, infrared radiation property, etc.), biofunctional functions (biocompatibility, anti-thrombus property, etc.) and the like.

In addition, a functional part used in such the functional element varies greatly depending on the function of a functional element, a method of forming a functional element and the like. In addition, a functional part-forming coating solution for forming a functional part is not particularly limited as far as it is liquid-like, and as an aspect thereof, there can be contemplated various aspects such as a composition not diluted with a solvent, a representative of which is an ultraviolet-ray curing type monomer, and a liquid composition diluted with a solvent.

Examples of such the functional element include a color filter, an EL element and the like.

2. Process for Manufacturing an EL Element

Then, a process for manufacturing an EL element of the present invention will be explained. The process for manufacturing an EL element of the present invention can be also roughly classified into two embodiments. Each embodiment will be explained below.

### (1) First Embodiment

A process for manufacturing an EL element of the present embodiment comprises:
a process of forming a photocatalyst-containing layer comprising at least a photocatalyst and a binder and also having the wettability changing such that a contact angle between water is reduced by irradiation of the energy, on a substrate having an electrode layer,
a process of forming a pattern comprising a water-repellent region and a hydrophilic region by irradiating the photocatalyst-containing layer with the energy in a pattern,
a process of electrifying the water-repellent region with a charge, and
a process of forming a pattern of an organic EL layer on the hydrophilic region by discharging and coating an organic EL layer-forming coating solution thereon by a nozzle discharging method.

One example of a process for manufacturing an EL element of the present embodiment is shown FIG. 1 as described above. The process for manufacturing an EL element comprises, like the process for manufacturing a pattern forming body as described above; a photocatalyst-containing layer forming process (FIGS. 1A and 1B) of forming a photocatalyst-containing layer 4 on a substrate 1 on which a transparent electrode 2 and an insulating layer 3 are formed; a pattern exposing process (FIG. 1C) of irradiating a substrate 1 on which this photocatalyst-containing layer 4 is formed, with ultraviolet light 6 in a pattern using a photomask 5; whereby, a part irradiated with ultraviolet light 6 becomes a hydrophilic region 7, and unirradiated part becomes water-repellent region 8, an electrification treatment process (FIG. 1D) of electrifying this water-repellent region 8; an organic EL layer-forming coating solution coating process (FIG. 1E) of coating a light-emitting layer-forming coating solution 9 for forming a light-emitting layer on the hydrophilic region 7 by discharging the solution with an ink jet apparatus 10; and an EL element completing process (FIG. 1F) of forming light-emitting layer 11 by solidifying this light-emitting layer-forming coating solution 9.

A. Photocatalyst-Containing Layer Forming Process

In the present invention, an electrode layer or an insulating layer may be formed on a transparent substrate in advance upon formation of a photocatalyst-containing layer. Further, a photocatalyst-containing layer is formed on a substrate on which such the electrode layer or insulating layer are formed. Since these photocatalyst-containing layer and substrate are the same as those explained in the item of a process for manufacturing the aforementioned pattern forming body, explanation is omitted. An electrode layer and an insulating layer which are the features of the process for manufacturing an EL element will be explained below.

a. Electrode Layer

The EL element obtained by the present invention has a first electrode layer formed on a substrate, and a second electrode layer formed on an organic EL layer such as a light-emitting layer and the like. Such the electrode layer is composed of a cathode and an anode, either of a cathode and an anode is transparent or transluscent and, as a cathode, an electrically-conducting material having a great work function is preferable for easy injection of positive holes. Alternatively, a plurality of materials may be mixed. Either of electrode layers has preferably a small resistance as possible, a metal material is generally used, and an organic or inorganic compound may be used.

Examples of a preferable cathode material include ITO, indium oxide and gold. Examples of a preferable anode material include magnesium alloy (MgAg etc.), aluminium alloy (AlLi, AlCa, AlMg etc.), metal calcium and metals having a small work function.

b. Insulating Layer

An EL element obtained by the present invention may be provided with an insulating layer in advance so that a light-emitting part is an opening, in order to cover a patterned edge part of a first electrode layer formed on a substrate and a non-light-emitting part of an element, and preventing short circuit with parts unnecessary for light-emitting. By adopting these features, defect of an element due to short circuit is reduced, and an element having a long life and stably light emitting is obtained.

Such the insulating layer may be pattern-formed using, for example, a UV curing resin material or the like as is normally known.

B. Pattern Exposing Process and C. Electrification Treatment Process

Since a pattern exposing process and an electrification treatment process in the present invention are the same as those for a process for manufacturing the aforementioned pattern forming body, explanation is omitted herein.

D. Organic EL Layer-Forming Coating Solution Coating Process

Since an organic EL layer-forming coating solution coating process in the present invention is almost the same as the functional part-forming coating solution coating process in a process for manufacturing the aforementioned pattern forming body except that a coating solution to be coated is embodied, explanation regarding a coating method and the like will be omitted herein. An organic EL layer-forming coating solution to be coated by the method of the present invention will be explained below.

(Organic EL Layer-Forming Coating Solution)

An organic EL layer in the present invention denotes a light-emitting layer, a buffer layer, a hole transporting layer, a hole injecting layer, an electron transporting layer, an electron injecting layer and the like, a coating solution upon formation of these respective layers is an organic EL layer-forming coating solution in the present invention. However, since a buffer layer and a light-emitting layer are the examples which, an organic EL layer is necessary to be formed in a pattern in an EL element, as an organic EL layer-forming coating solution in the resent invention, it can be said that a light-emitting layer-forming coating solution and a buffer layer-forming coating solution are the main ones.

(Light-Emitting Layer-Forming Coating Solution)

In an EL element, a light-emitting layer is an essential layer, and is a layer inevitably requiring patterning. Therefore, in the present invention, the case where an organic EL layer-forming coating solution is a light-emitting layer-forming coating solution is the most preferable aspect in respect of the effectiveness of an invention.

The light-emitting layer-forming coating solution used in the present invention is usually composed of a light-emitting material, a solvent, and an additive such as a doping agent and the like. In the case of conducting full colorization, since a light-emitting layer for a plurality of colors is formed, a plurality kinds of light-emitting layer-forming coating solutions are usually used. Each material constituting these light-emitting layer-forming coating solutions will be explained below.

a. Light-Emitting Material

Examples of a light-emitting material used in the present invention include a pigment series material, a metal complex series material, and a polymer series material.

\mathring{1} Pigment Series Material

Examples of a pigment series material include a cycropendamine derivative, a tetraphenylbutadiene derivative, a triphenylamine derivative, an oxadiazole derivative, a pyrazoloquinoline derivative, a distyrylbenzene derivative, a distyrylarylene derivative, a sirol derivative, a thiophene ring compound, a pyridine ring compound, a perynone derivative, a perylene derivative, an oligothiophene derivative, a trifumarylamine derivative, an oxadiazole dimer, a pyrazoline dimer and the like.

\mathring{2} Metal Complex Series Material

Examples of a metal complex series material include metal complexes having Al, Zn, Be, and the like, a rare earth metal such as Tb, Eu, Dy and the like as a central metal, and having an oxadiazole, thiadiazole, phenylpyrydine, phenylbenzoimidazole, or quinoline structure as a ligand such as an alumiquinolinol complex, a benzoquinolinolberyllium complex, a benzooxazole zinc complex, a benzothiazole zinc complex, an azomethyl zinc complex, a porphyrin zinc complex, a europium complex and the like.

\mathring{3} Polymer Series Material

Examples of a polymer series material include a polyparaphenylenevinylene derivative, a polythiophene derivative, a polyparaphenylene derivative, a polysilane derivative, a polyacetylene derivative, a polyfluorene derivative, a polyvinylcarbazole derivative, and materials obtained by polymerizing the aforementioned pigments, or metal complex series light-emitting materials.

In the present invention, from a viewpoint of utilizing the advantage that a light-emitting layer can be formed at a better precision by a nozzle discharging method using a light-emitting layer-forming coating solution, it is preferable that the aforementioned polymer series materials are used as a light-emitting material.

b. Solvent

A solvent which dissolves or disperses the aforementioned light-emitting material to obtain a light-emitting layer-forming coating solution is not particularly limited as far as it is a solvent which dissolves or disperses the aforementioned light-emitting material and also has a prescribed viscosity.

Specifically, there are chloroform, methylene chloride, dichloroethane, tetrahydrofuran, toluene, xylene and the like.

c. Additive

A variety of additives can be added to a light-emitting layer-forming coating solution used in the present invention in addition to the aforementioned light-emitting materials and solvents. For example, a doping material is added in some cases for the purpose of improving the light-emitting efficacy in a light-emitting layer, or changing a light emitting wavelength. Examples of this doping material include a perylene derivative, a coumarin derivative, a rubulene derivative, a quinacridone derivative, a squarylium derivative, a porphyren derivative, a styryl series pigment, a tetracene derivative, a pyrazoline derivative, decacyclene, phenoxazine and the like.

(Buffer Layer-Forming Coating Solution)

A buffer layer in the present invention is a layer provided between a cathode and a light-emitting layer or between an anode and a light-emitting layer so that injection of charges into a light-emitting layer can be easily conducted, and containing an organic material, in particular, an organic electrically-conducting pair. For example, by enhancing the efficacy of injecting holes into a light-emitting layer, an electrically-conducting polymer having the function of flattening the irregularity of an electrode can be obtained.

Since it is desirable that such the buffer layer is patterned in order to retain the diode property of an element and prevent crosstalk in the case of high electrically-conducting property, it is preferable that patterning is conducted using a process of the present invention.

Examples of a material for forming a buffer layer used in the present invention include polymerized hole transporting substances such as a polyalkylthiophene derivative, a polyaniline derivative, a triphenylamine and the like, sol or gel membranes of inorganic oxides, polymerized membranes of an organic substance such as trifluoromethane, organic compound membranes containing Lewis acid and the like. Solutions or dispersions of them in solvents such as water, alcohols such as methanol ethanol and the like, dimethylformamide, dimethylacetamide, dimethyl sulfoxide, N-methyl-2-pyrrolidone and the like are buffer layer-forming coating solutions in the present invention.

(Regarding Electrification of an Organic EL Layer-Forming Coating Solution)

In a process for manufacturing an EL element of the present invention, it is preferable that such the organic EL layer-forming coating solution is electrified with the same kind of charge as that of a water-repellent region.

Since this electrification method is the same as that explained for the aforementioned pattern forming body, explanation is omitted herein.

In addition, as explained in the item of a process for manufacturing the aforementioned pattern forming body, in the case where a droplet of an organic EL layer-forming coating solution discharged by a nozzle discharging method is electrified, it is preferable that voltage of a different charge from that of an organic EL layer-forming coating solution is applied to a transparent electrode layer.

E. EL Element Completing Process

In the present invention, as described above, by drying and solidifying an organic EL layer-forming coating solution, an organic EL layer is formed, the aforementioned second electrode layer and the like are formed thereon, and sealed with a sealer, whereby, an EL element can be obtained.

### (2) Second Embodiment

A process for manufacturing an EL element in the present embodiment comprises:
a process of forming a pattern comprising an electrode layer and an insulating layer by forming an insulating layer so as to cover an edge part of the electrode layer and a non-light-emitting layer of an organic EL layer, on a substrate having an electrode layer formed in a pattern,
a process of electrifying the insulating layer with a charge, and
a process of forming a pattern of an organic EL layer by discharging and coating an organic EL layer-forming coating solution on the electrode layer by a nozzle discharging method.

One example of a process for manufacturing an EL element of the present embodiment is shown in the aforementioned FIG. 2. Also in this case, a transparent electrode layer 22 is formed on a substrate 21 in a pattern (FIG. 2A) and, then, an insulating layer 23 is formed so as to cover an end of the transparent electrode layer 22 and a region on which no transparent electrode layer 22 is formed (FIG. 2B; Insulating layer pattern-forming process). Here, an insulating layer 23 is formed protruding from a transparent electrode layer 22.

And, the insulating layer 23 is electrified by electrification treatment (FIG. 2C; Electrification treatment process).

A light-emitting layer 11 is formed by discharging a light-emitting layer-forming coating solution 9 to the electrification-treated substrate 21 with an ink jet apparatus 10 (FIG. 2D; Organic EL layer-forming coating solution coating process), and curing the solution (FIG. 2E; EL element completing process).

In the present embodiment, it is preferable that an insulating layer is formed protruding from an electrode layer as described above. Upon this, it is preferable that a protruded amount is in a range of 0.0 μm to 100 μm, more preferably in a range of 0.1 μm to 10 μm.

Since explanation regarding other respective processes of the present embodiment can be performed by combing methods and materials used in respective processes of the aforementioned first embodiment, explanation is omitted herein.

3. Process for Manufacturing a Color Filter

Finally, a process for manufacturing a color filter of the present invention will be explained. A process for manufacturing a color filter of the present invention comprises:
a process of forming a photocatalyst-containing layer comprising at least a photocatalyst and a binder and having the wettability which is changed so that a contact angle between water is reduced by irradiation of the energy, on a transparent substrate,
a process of forming a pattern comprising a water-repellent region and a hydrophilic region by irradiating the photocatalyst-containing layer with the energy in a pattern,
a process of electrifying the water-repellent region with a charge, and
a process of forming a pattern of a pixel part by discharging and coating a pixel part-forming coating solution on the hydrophilic region by a nozzle discharging method.

The process for manufacturing a color filter of the present invention is different from the process for manufacturing the aforementioned EL element is in that formed on a substrate in advance is a black matrix in a photocatalyst-containing layer forming process, and that a pixel part-forming coating solution is used in a functional part-forming coating solution coating process. Since other features are the same as those described for a process for manufacturing the aforementioned pattern forming body and for a process for manufacturing the aforementioned EL element, explanation is omitted herein.

(Black Matrix)

A black matrix used in the present invention is not particularly limited as far as it is a black matrix which is normally used in a color filter. For example, a light-shading part formed by forming patterning a thin metal membrane of chromium or the like having a thickness of around 1000 to 2000 Å by a sputtering method, or a vacuum deposition method, and a light-shading part containing a light-shading particle such as a carbon-fine particle a metal oxide, an inorganic pigment, an organic pigment and the like in a resin binder are used.

(Pixel Part-Forming Coating Solution)

As a pixel part-forming coating solution used in the present invention, a pixel part-forming coating solution of three colors of red (R), green (G) and blue (B) is usually used. Such the pixel part-forming coating solution is roughly classified into an aqueous solution and an oily solution, and either of them may be used in the present invention. In the context of a surface tension, a water-based aqueous coating solution is preferable.

In an aqueous coating solution used in the present invention, as a solvent, water alone or a mixed solvent of water and a water-soluble organic solvent can be used. On the other hand, in an oily coating solution, a solvent based on a solvent having a high boiling point is preferably used for preventing clogging of a head. As a colorant used in such the pixel part-forming coating solution, the known pigments and dyes are used widely. In addition, for improving the dispersing property and the fixing property, a solvent may contain insoluble or soluble resins. Besides, surfactants such as a nonionic surfactant, a cationic surfactant and an amphoteric surfactant; a preservative; a mildewcide; a pH adjusting agent; an anti-foam; an ultraviolet absorbing agent; a viscosity adjusting agent; a surface tension adjusting agent and the like, if necessary, may be added.

In addition, although a normal pixel part-forming coating solution can not contain a large amount of a binder resin due to low suitable viscosity, by particulating a colorant particle in a coating solution by wrapping with a resin, the fixing ability can be imparted to a colorant itself. Such the coating solution can be also used in the present invention. Further, a so-called hot melt type coating solution and an UV curing type coating solution may be used.

In the present invention, it is preferable to use an UV curing type, inter alia. By adopting an UV curing pixel part-forming coating solution, rapid curing and immediate feeding to the next process become possible by coloring by a nozzle discharging method to form a pixel part, followed by irradiation. Therefore, a color filter can be made effectively.

Such the UV curing type pixel part-forming coating solution contain a prepolymer, a monomer, a photoinitiator and a colorant as a main component. As the prepolymer, any of prepolymers such as polyester acrylate, polyurethane acrylate, epoxy acrylate, polyether acrylate, oligoacrylate, alkyd acrylate, polyol acrylate, silicone acrylate and the like can be used, without any limitation.

As the monomer, vinyl monomers such as styrene, vinyl acetate and the like; monofunctional acryl monomers such as n-hexyl acrylate, phenoxyethyl acrylate and the like; polyfunctional acryl monomers such as diethylene glycol diacrylate, 1,6-hexanediol diacrylate, hydroxypiperic acid ester neopentyl glycol diacrylate, trimethylolpropane triacrylate, dipentaerythritol hexaacrylate and the like can be used. The aforementioned prepolymers and monomers may be used alone or two or more may be mixed.

As the photoinitiator, photoinitiator by which the desired curing property is obtained can be used by selecting from isobutyl benzoin ether, isopropyl benzoin ether, benzoin ethyl ether, benzoin methyl ether, 1-phenyl-1,2-propanedione-2-oxime, 2,2-dimethoxy-2-phenylacetophenone, benzil, hydroxycyclohexyl phenyl ketone, diethoxyacetophenone, 2-hydroxy-2-methyl-1-phenylpropane-1-one, benzophenone, chlorothioxanthone, 2-chlorothioxanthone, isopropylthioxanthone, 2-methylthioxanthone, chlorine-substituted benzophenone, halogen-substituted alkyl-allyl ketone and the like. If necessary, photoinitiator aids such as aliphatic amines, aromatic amines and the like; photosensitizers such as thioxanthone and the like may be added thereto.

Also in the present invention, it is preferable that a pixel part-forming coating solution is electrified with the same kind charge as that of a water-repellent region.

As described above, the present invention has been explained, but is not limited to the aforementioned embodiments. The aforementioned embodiments are merely an example, and any embodiments having substantially the same features as the technical ideas described in claims and exerting the same effects and advantages are included in the scope of the present invention.

### EXAMPLES

The present invention will be further explained by way of Examples.

### Example 1

### Preparation of a Substrate

A film of ITO was formed on PET by sputtering having a thickness of 200 μm, ITO having a line width of 80 μm was patterned at an interval of 20 μm, and an insulating layer having a thickness of 1 μm was formed between ITO by a photolithography method so as to cover an edge of an ITO pattern. In an insulating layer, ZPP-1850 (ZEON Corporation) was used as a resist.

Then, polyethylenedioxythiophene/polystyrenesulfonate (PEDT/PSS) (Baytrin P: manufactured by Bayer, the structure is shown in the following formula (1)) as a coating solution for a buffer layer was spin-coated on a substrate at 700 Å at drying, and vacuum drying was performed at 100° C. for 1 hour. 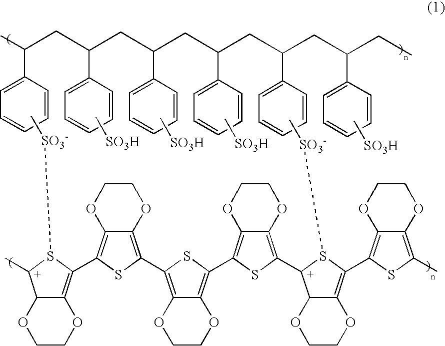
(Formation of a Photocatalyst-Containing Layer)

1. Preparation of a Photocatalyst-Containing Layer Coating Solution

First, a coating solution for a photocatalyst-containing
layer having the following composition was prepared:

| | |
|---|---|
| Photocatalyst-containing layer composition (ST-K01 | 2 parts by weight |
| manufactured by Ishihara Sangyo Kaisha, Ltd.) | |
| Organoalkoxysilane (TSL8113 manufactured by | 0.4 part by weight |
| Toshiba Silicones) | |
| Fluoroalkoxysilane (MF-160E manufactured by | 0.3 part by weight |
| Tohkem Products | |
| Isopropyl alcohol | 3 parts by weight |

2. Preparation of a Film of a Photocatalyst-Containing Layer

The aforementioned photocatalyst-containing layer coating solution was coated on a cleaned glass substrate with a spin coater, dried at 150° C. for 10 minutes, and a hydrolysis reaction and a polycondensation reaction were allowed to proceed, to form a transparent photocatalyst-containing layer having a thickness of 20 nm in which a photocatalyst was fixed firm in organosiloxane.

3. Formation of a Pattern Due to a Difference in the Wettabilities in a Photocatalyst-Containing Layer

The aforementioned photocatalyst-containing layer Was irradiated in a pattern at an illuminance of 7 mW/cm² for 50 seconds with a mercury lamp (wavelength 365 nm) via a mask, contact angles relative to water of an irradiated part and a non-irradiated part were measured using a contact angle measuring equipment (Model CA-Z manufactured by Kyowa Interface Science Co., LTD.) (30 seconds after addition dropwise of a water droplet with a microsyringe) and, as a result, a contact angle of a non-irradiated part of water was 142°, while a contact angle of water at an irradiated part was 10° C. or smaller, and it was confirmed that the formation of a pattern due to a difference in the wettabilities between an irradiated part and a non-irradiated part is possible.

(Electrification Treatment)

After patterns different in the wettablity were formed on the photocatalyst-containing layer as described above, the whole plane was electrified with +6 kV. Upon this, at an exposed part (hydrophilic part), an electrified amount was +1V and, at an unexposed part (water-repellent region), an electrified amount was +120V.

(Preparation of a Film of a Light-Emitting Layer)

Thereafter, a light-emitting layer coating solution was coated thereon by an ink jet method. This light-emitting layer coating solution has the following composition:

Composition of a Light-Emitting Layer Coating Solution

| | |
|---|---|
| Polyvinyl carbazole | 7 parts by weight |
| Light-emitting pigment (R, G, B) | 0.1 part by weight |
| Oxadiazole compound | 3 parts by weight |
| Toluene | 5050 parts by weight |

Herein, the structural formula of polyvinyl carbazole is shown in the following chemical formula (2). In addition, the structural formula of a oxadiazole compound is shown in the chemical formula (3), the structural formula of a light-emitting pigment (G) coumarin 6 is shown in the chemical formula (4), the structural formula of a light-emitting pigment (R) Nile Red is shown in the chemical formula (5), and the structural formula of a light-emitting pigment (B) perylene compound is shown in the chemical formula (6), respectively. 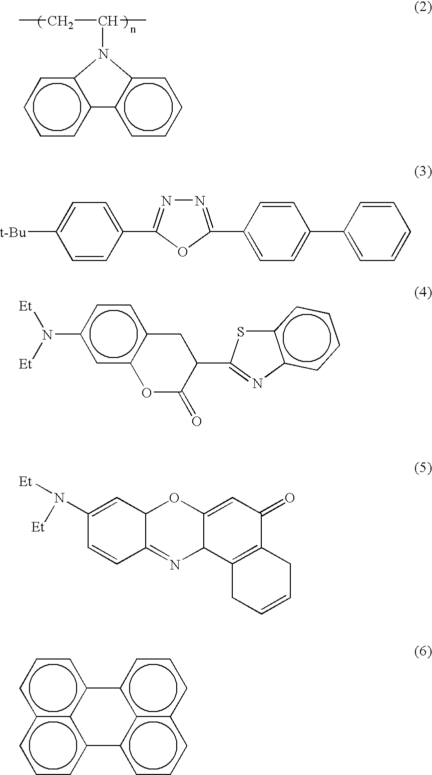
(Preparation of a Film of a Cathode)

An AlLi alloy was deposited at a thickness of 500 nm, a line width of 80 μm and an interval of 20 μm as an upper electrode, on a substrate on which a light-emitting layer had been formed, so as to be orthogonal with patterns of ITO and a light-emitting layer, to obtain an EL element.

### Example 2

An EL element was prepared according to the same process as that of Example 1 except that electrification of the whole plane was −6 kV.

### Example 3

An EL element was prepared according to the same process as that of Example 1 except that a coating solution was discharged while corona-electrifying a discharging head, upon coating with an ink jet method.

### Example 4

An EL element was prepared according to the same process as that of Example 1 except that coating was performed by an ink jet method in the state where voltage of +100V relative to a head was applied to an ITO electrode side.

### Example 5

An EL element was prepared according to the same process as that of Example 1 except that a photocatalyst-containing layer was not formed.

### Comparative Example

An EL element was prepared according to the same process as that of Example 1 except that electrification treatment was not performed.

Evaluation

In the resulting EL element, an ITO electrode side was connected to a positive electrode, an AlLi alloy electrode side was connected to a negative electrode, and a DC current was applied with a sourcemeter.

In EL elements obtained in Examples 1 to 5, each color of the above R, G and R was emitted on a line, and color mixing was not perceived at application of 10V, while in an EL element obtained in Comparative Example, places where partial mixing were observed.

1-25. (canceled)

26. A process for manufacturing a pattern forming body, which comprises:
a process of forming a photocatalyst-containing layer comprising at least a photocatalyst and a binder and having a wettability which is changed so that a contact angle between water is reduced by irradiation of the energy, on a substrate;
a process of forming a pattern comprising a water-repellent region and a hydrophilic region by irradiating the photocatalyst-containing layer with the energy in a pattern;
a process of electrifying the water-repellent region with a charge;
a charge-electrified pattern-forming process of forming a pattern comprising a charge-electrified region electrified with a charge and a charge-nonelectrified region electrified with no charge, on a substrate; and
a functional part pattern-forming process of forming a pattern of a functional part by discharging and coating a functional part-forming coating solution on the charge-nonelectrified region by a nozzle discharging method.

27. The process for manufacturing a pattern forming body according to claim 26, wherein the functional part-forming coating solution discharged by a nozzle discharging method is electrified with the same kind of charge as that of the charge-electrified region.

28. The process for manufacturing a pattern forming body according to claim 26, wherein the nozzle discharging method is an ink jet method.

29. The process for manufacturing a pattern forming body according to claim 26, wherein the energy to be irradiated to the photocatalyst-containing layer is the light containing the ultraviolet light.

30. The process for manufacturing a pattern forming body according to claim 26, wherein the photocatalyst-containing layer contains fluorine, and the photocatalyst-containing layer is formed so that the fluorine content is reduced on the surface of the photocatalyst-containing layer it reduced by the action of the photocatalyst upon irradiation of the photocatalyst.-containing layer with the energy, as compared with before irradiation with the energy.

31. The process for manufacturing a pattern forming body according to claim 26, wherein the photocatalyst is 1 kind, or 2 or more kinds of substance(s) selected from titanium oxide (TiO₂), zinc oxide (ZnO), tin oxide (SnO₂), strontium titanate (SrTiO₃), tungsten oxide (WO₃), bismuth oxide (Bi₂O₃) and iron oxide (Fe₂O₃).

32. The process for manufacturing a pattern forming body according to claim 31, wherein the photocatalyst is titanium oxide (TiO₂).

33. The process for manufacturing a pattern forming body according to claim 26, wherein the photocatalyst-containing layer is such that a contact angle between water of a part not irradiated with the energy is greater than that of a part irradiated with the energy by one degree or greater.

34. The process for manufacturing a pattern forming body according to claim 26, wherein the binder is organosiloxane which is 1 kind, or 2 or more kinds of hydrolysis-condensates or co-hydrolysis-condensates of silicon compounds represented by YₙSiX₍₄₋ₙ₎ (wherein Y denotes an alkyl group, a fluoroalkyl group, a vinyl group, an amino group, a phenyl group or an epoxy group, X denotes an alkoxyl group or halogen, and t is an integer of 0 to 3).

35. A process for manufacturing an electroluminescent element using the process for manufacturing a pattern forming body according to claim 26, which comprises:
a process of forming a photocatalyst-containing layer comprising at least a photocatalyst and a binder and having a wettability which is changed so that a contact angle between water is reduced by irradiation of the energy, on a substrate having an electrode layer;
a process of forming a pattern comprising a water-repellent region and a hydrophilic region by irradiating the photocatalyst-containing layer with the energy in a pattern;
a process of electrifying the water-repellent region with a charge; and
a process forming a pattern of an organic electroluminescent layer by discharging and coating an organic electroluminescent layer-forming coating solution on the hydrophilic region by a nozzle discharging method.

36. The process for manufacturing an electroluminescent element according to claim 35, wherein the organic electroluminescent layer-forming coating solution is electrified with the same kind of charge as that of the water-repellent region.

37. The process for manufacturing an electroluminescent element according to claim 35, wherein the electrode layer is formed on the substrate in a pattern, an insulating layer is formed so as to cover an edge part of the electrode layer and a non-light-emitting part of an organic electroluminescent layer, and voltage is applied to the electrode layer with a different kind of charge from that of the water-repellent region, upon discharging and coating of the organic electroluminescent layer-forming coating solution by the nozzle discharging method.

38. The process for manufacturing an electroluminescent element according to claim 35, wherein the nozzle discharging method is an ink jet method.

39. The process for manufacturing an electroluminescent element according to claim 35, wherein the Organic electroluminescent layer is a light-emitting layer.

40. A process for manufacturing a color filter using the process for manufacturing a pattern forming body according to claim 35, which comprises:
a process of forming a photocatalyst-containing layer comprising at least a photocatalyst and a binder and having the wettability which is changed so that a contact angle between water is reduced by irradiation of the energy, on a transparent substrate;
a process of forming a pattern comprising a water-repellent region and a hydrophilic region by irradiating the photocatalyst-containing layer with the energy in a pattern;
a process of electrifying the water-repellent region with a charge; and
a process of forming a pattern of a pixel part by discharging and coating a pixel part-forming coating solution on the hydrophilic region by a nozzle discharging method.

41. The process for manufacturing a color filter according to claim 40, wherein the pixel part-forming coating solution is electrified with the same kind of charge as that of the water-repellent region.

42. The process for manufacturing a color filter according to claim 40, wherein the nozzle discharging method is an ink jet method.
